(19) United States
(12) Patent Application Publication
(10) Pub. No.: US 2013/0170159 A1
(43) Pub. Date: Jul. 4, 2013

(54) HOUSING FOR PORTABLE ELECTRONIC DEVICES

(71) Applicant: QIU-SHENG JIANG, Shenzhen City (CN)

(72) Inventor: QIU-SHENG JIANG, Shenzhen City (CN)

(73) Assignees: CHI MEI COMMUNICATION SYSTEMS, INC., Tu-Cheng (TW); SHENZHEN FUTAIHONG PRECISION INDUSTRY CO., LTD., ShenZhen City (CN)

(21) Appl. No.: 13/614,593

(22) Filed: Sep. 13, 2012

(30) Foreign Application Priority Data
Dec. 29, 2011 (CN) 201110450660.6

(51) Int. Cl. H05K 5/03; H05K 5/02

(52) U.S. Cl. 361/753; 361/752; 312/223.1

(57) ABSTRACT

A housing for a portable electronic device includes a first housing member. The first housing member includes a metal member and a plastic member integrally molded with the metal member. The metal member includes a main portion and a peripheral wall perpendicular to the main portion. The peripheral wall defines a plurality of notches. Each notch is substantially wedge-shaped with a top opening smaller than a bottom thereof. The peripheral wall tightly abuts against the plastic member with portions of the plastic member filling in the notches.

### BACKGROUND

1. Technical Field

The present disclosure relates to a housing for portable electronic devices, and particularly to a housing made from metal and plastic.

2. Description of related art

To obtain a reduced thickness and a reduced weight, housings for portable electronic devices are manufactured by insert-molding using a metal sheet having a thickness of about 0.2 mm as an insert. However, because the metal sheet is thin, the housings are easily deformed in use, reducing the structural strength of the housings. Moreover, non-uniform shrinkage during cooling of plastic molded with the metal sheet easily causes spaces between the plastic and the metal sheet.

Therefore, there is room for improvement within the art.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the disclosure. Moreover, in the drawing like reference numerals designate corresponding parts throughout the views.

FIG. 1 is an exploded view of a housing in accordance with an exemplary embodiment.

FIG. 2 is an enlarged cross-sectional view of a circled portion II of FIG. 1.

FIG. 3 is an exploded view of the housing of FIG. 1 viewed from another angle.

FIG. 4 is an isometric view of the housing of FIG. 1.

FIG. 5 is a cross-sectional view of the housing of FIG. 4 taken along line IV-IV.

FIG. 6 is a cross-sectional view of the housing of FIG. 4 taken along line V-V.

### DETAILED DESCRIPTION

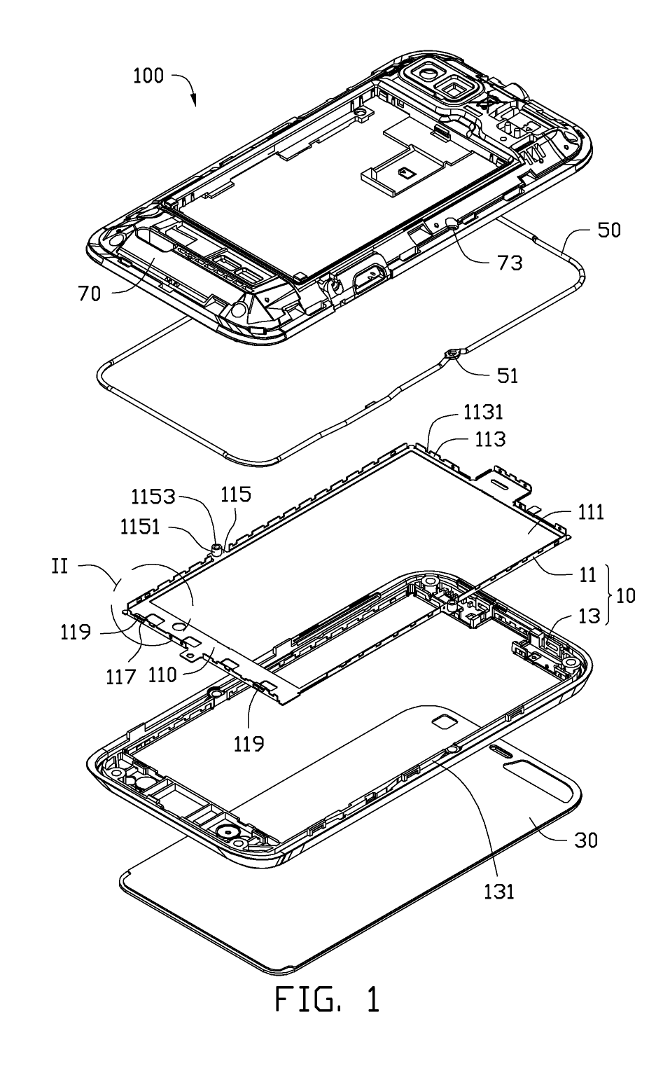

FIG. 1 shows an exemplary embodiment of a housing 100 for portable electronic devices, such as mobile phones and personal digital assistant. In the exemplary embodiment, the housing 100 is a housing of a mobile phone. The housing 100 includes a first housing member 10, a touch screen 30, a waterproof member 50, and a second housing member 70. The touch screen 30 is secured on the first housing member 10. The second housing member 70 is covered on the first housing member 10. The waterproof member 50 is located between the first housing member 10 and the second housing member 70.

The first housing member 10 includes a metal member 11 and a plastic member 13 integrally molded with the metal member 11.

The metal member 11 is made from a metal sheet, such as iron, steel, or aluminum alloy. In the exemplary embodiment, the metal member 11 is made from a steel sheet having a thickness of about 0.2 mm. The metal member 11 includes a main portion 110, peripheral wall 113, two extending portions 115, and at least one clasp portion 117.

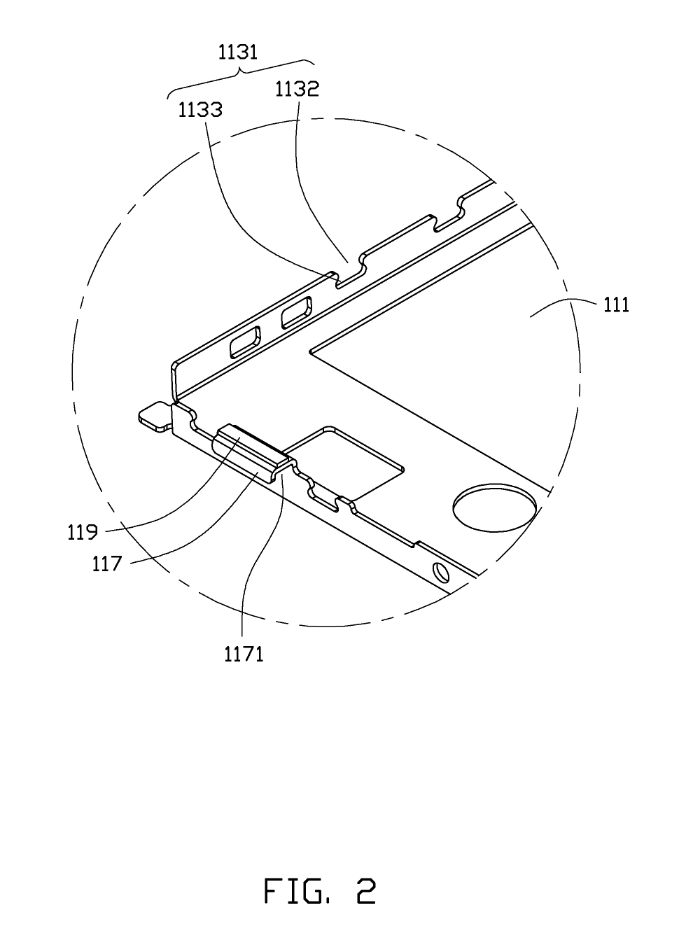

Referring to FIGS. 1 and 2, the main portion 110 is substantially a rectangular board and defines a receiving hole 111 in a middle portion through the main portion 110. The receiving hole 111 is used for receiving the touch screen 30. The peripheral wall 113 extends from a peripheral edge of the main portion 110 and is perpendicular to the main portion 110. The peripheral wall 113 defines a plurality of notches 1131. In the exemplary embodiment, each notch 1131 is substantially wedge-shaped, that is, the top opening 1132 of each notch 1131 is smaller than the bottom 1133. The peripheral wall 113 tightly abuts against the plastic member 13 with portions of the plastic member 13 filling in the notches 1131. Thus, the plastic member 13 and the metal member 11 tightly lock together and prevent space forming between the metal member 11 and the plastic member 13. Therefore, first housing member 10 is waterproof.

The two extending portions 115 extend away from two opposite edges of the main portion 110, respectively. Each extending portion 115 is substantially rectangular. Each extending portion 115 has an assembling post 1151 secured thereon. Each assembling post 1151 defines a first hole 1153. The assembling posts 1151 are used for assembling the second housing member 70 to the first housing member 10.

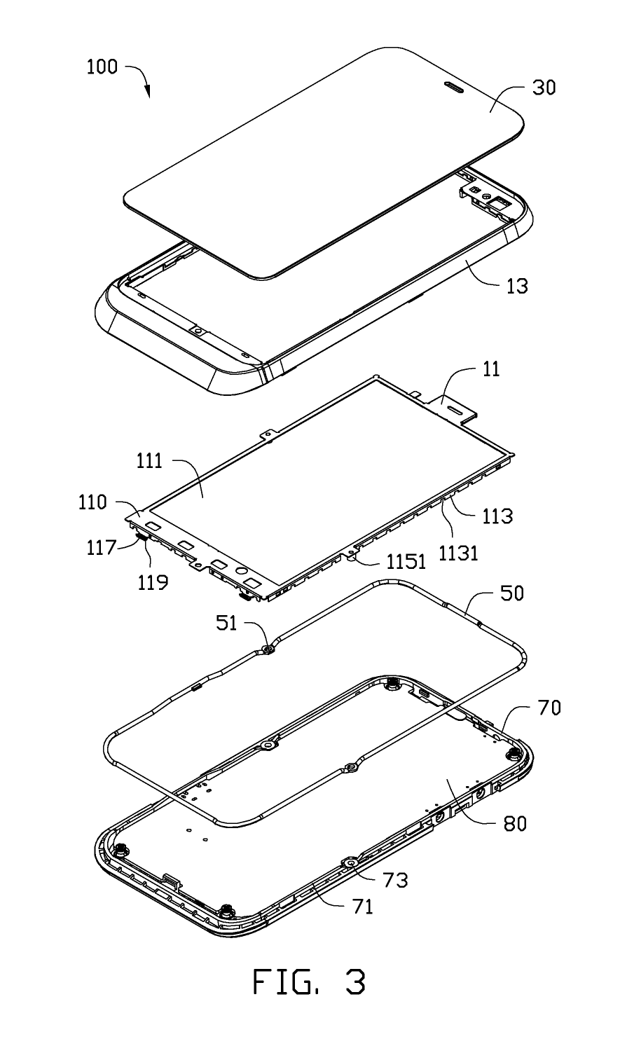

Referring to FIG. 2, the at least one clasp portion 117 extends upwardly from the peripheral wall 113, bends along a direction parallel to the main portion 110, and then bends toward the main portion 110, thereby forming a clasping space 1171. The clasping space 1171 receives a peripheral wall of the plastic member 13. When the metal member 11 is bonded with the plastic member 13, the at least one clasping portion 117 is exposed out of the plastic member 13. Thus, the at least one clasping portion 117 also is used to conductively connect to a grounding terminal (not shown) on a circuit board 80 (see FIG. 3) secured inside the housing 100, thereby guiding static electricity produced by the housing 100 to the ground. The at least one clasping portion 117 may connect to the grounding terminal through a conductive member 119 touching both the at least one clasping portion 117 and the grounding terminal In the exemplary embodiment, the conductive member 119 is a conductive foam adhered on the at least one clasping portion 117.

The plastic member 13 is molded from plastic, such as polypropylene (PP), polyamide (PA), polycarbonate (PC), polyethylene terephthalate (PET), or polymethyl methacrylate (PMMA). The plastic member 13 defines a receiving recess 131. The receiving recess 131 is substantially annular.

The touch screen 30 may be a capacitive touch screen and may have a thickness of about 1.05 mm. The touch screen 30 can be secured in the receiving hole 111 by a waterproof adhesive.

The waterproof member 50 is made of an elastic material (such as rubber) and has a shape corresponding to the shape of the receiving recess 131. The waterproof member 50 can be received in the receiving recess 131 of the plastic member 13. The waterproof member 50 defines second holes 51 corresponding to the first holes 1153.

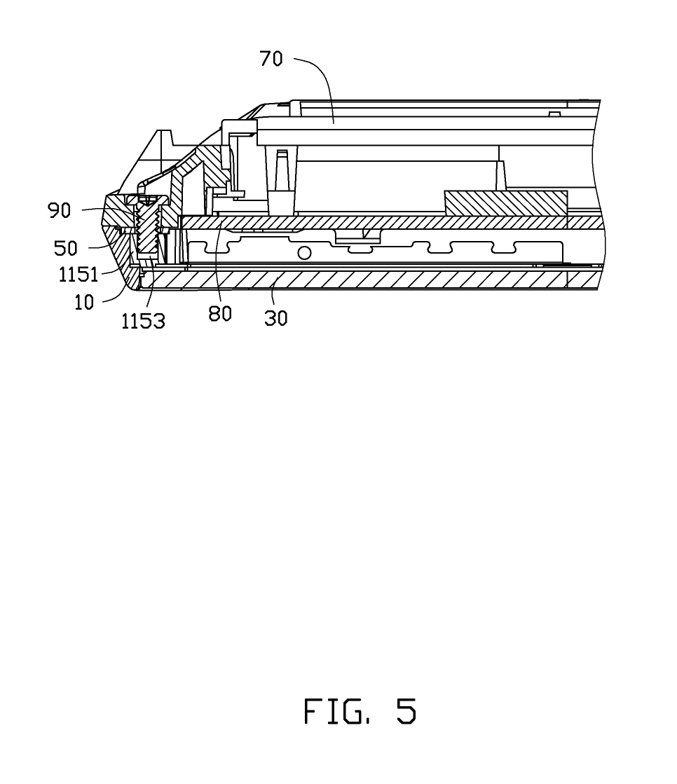

Referring to FIG. 3, the second housing member 70 has a shape engageable with the first housing member 10. The second housing member 70 may be made of plastic, such as PP, PA, PC, PET, or PMMA. The second housing member 70 has a rib 71 formed on a side facing the first housing member 10. The rib 71 has a shape corresponding to the shape of the receiving recess 131 and can be received in the receiving recess 131 to hold the waterproof member 50 in the receiving recess 131. The second housing member 70 defines third holes 73 corresponding to the first and second holes 1153, 51. The second housing member 70 and the first housing member 10 can be assembled together using screws 90 (see FIG. 5) to screw into the third, second, and first holes 73, 51, 1153, respectively.

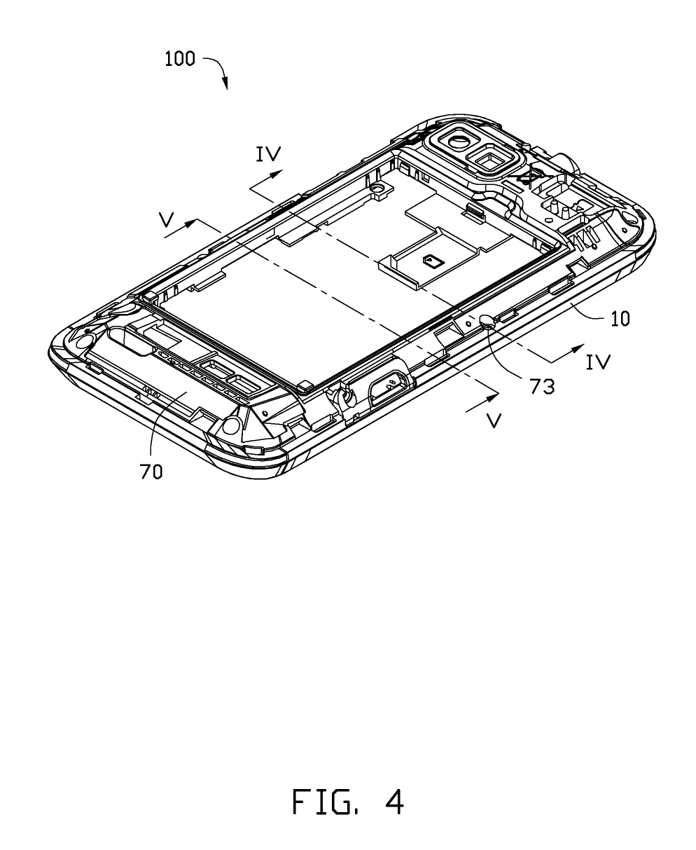

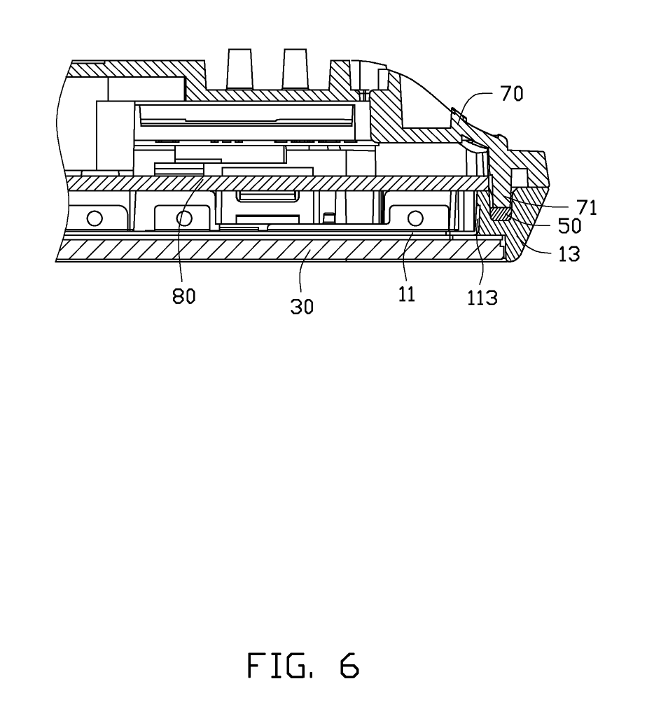

Referring to FIGS. 4 and 5, to assemble the housing 100, the waterproof member 50 is positioned into the receiving recess 131 of the first housing member 10 with the second holes 51 aligned with the third holes 73. Then, the second housing member 70 is covered onto the first housing member 10 with the rib 71 received in the receiving recess 131 and the at least one clasping portion 117 connected with the grounding terminal on the circuit board 80. The screws 90 are screwed into the third, second, and first holes 73, 51, and 1153, respectively, thereby assembling the first housing member 10 and the second housing member 70 together. Referring to FIG. 6, the waterproof member 50 is positioned between the first housing member 10 and the second housing member 70. When pressing the rib 71, the waterproof member 50 deforms to seal interspaces formed between the rib 71 and the receiving recess 131, achieving a waterproof effect.

The metal member 11 of the first housing member 10 has the at least one clasping portion 117 catching the plastic member 13, strengthening the bonding of the metal member 11 and the plastic member 13. Moreover, the at least one clasping portion 117 is conductively connected to the grounding terminal (not shown) on the circuit board 80 secured inside the housing 100, thereby guiding static electricity produced by the housing 100 to the ground without any additional grounding means.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A housing for a portable electronic device, comprising:
a first housing member including a metal member and a plastic member integrally molded with the metal member, the metal member including a main portion and a peripheral wall perpendicular to the main portion, the peripheral wall defining a plurality of notches, each notch being substantially wedge-shaped with a top opening smaller than a bottom thereof, the peripheral wall tightly abutting against the plastic member with portions of the plastic member filling in the notches.

2. The housing as claimed in claim 1, wherein the metal member further includes at least one clasp portion; the at least one clasp portion extends upwardly from the peripheral wall then bends along a direction parallel to the main portion, and then bends toward the main portion to form a clasping space; the clasping space receives a peripheral wall of the plastic member.

3. The housing as claimed in claim 2, wherein the at least one clasping portion is exposed out of the plastic member and conductively connects a circuit board secured inside the housing, thereby guiding static electricity produced by the housing to the ground.

4. The housing as claimed in claim 3, wherein the at least one clasping portion conductively connects the circuit board through a conductive member.

5. The housing as claimed in claim 4, wherein the conductive member is a conductive foam adhered on the at least one clasping portion.

6. The housing as claimed in claim 1, wherein the metal member made from a steel sheet having a thickness of about 0.2 millimeters.

7. The housing as claimed in claim 1, wherein the metal member defines a receiving hole in a middle portion; the housing further includes a touch screen; the touch screen is secured in the receiving hole by a waterproof adhesive.

8. The housing as claimed in claim 1, further comprising a waterproof member made of an elastic material and a second housing member; the second housing member is covered on the first housing member; the waterproof member is located between the first housing member and the second housing member.

9. The housing as claimed in claim 8, wherein the plastic member defines a receiving recess; the waterproof member is received in the receiving recess; the second housing member has a rib formed on a side facing the first housing member; the rib is received in the receiving recess to hold the waterproof member in the receiving recess.

10. The housing as claimed in claim 8, wherein the metal member has two extending portions extending away from two opposite edges of the main portion; each extending portion has an assembling post secured; each assembling post defines a first hole; the waterproof member defines second holes corresponding to the first holes; the second housing member defines third holes corresponding to the first and second holes; the second housing member and the first housing member are assembled together by screws screwing into the third, second, and first holes.

11. The housing as claimed in claim 1, wherein the plastic member is molded from a plastic material selected from the group consisting polypropylene, polyamide, polycarbonate, polyethylene terephthalate, and polymethyl methacrylate.
